(19) United States
(12) Patent Application Publication
(10) Pub. No.: US 2025/0264527 A1
(43) Pub. Date: Aug. 21, 2025

(54) INSERT AND AUTOMATED MOUNTING TEST SYSTEM FOR TESTING SEMICONDUCTOR PRODUCT IN STANDING STATE

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Han Su BAE, Siheung-si (KR)

(21) Appl. No.: 19/057,712

(22) Filed: Feb. 19, 2025

(30) Foreign Application Priority Data
Feb. 20, 2024 (KR) 10-2024-0024575
Jan. 22, 2025 (KR) 10-2025-0009730

(51) Int. Cl. G01R 31/28; G01R 1/04

(52) U.S. Cl. CPC G01R 31/2893; G01R 1/0466; G01R 31/2891

(57) ABSTRACT

An automated mounting test system for testing a semiconductor product in a standing state according to one embodiment of the present disclosure includes a test tray including a plurality of inserts and having a tray groove into which each insert is inserted, a handler configured to load a semiconductor product to be tested into an empty insert and collect the tested semiconductor product from the insert, a tester including a plurality of socket modules, each facing one of the inserts, in a state where the test tray is seated, and a rack master configured to transport the test tray between the handler and the tester.

### CROSS-REFERENCE TO RELATED APPLICATIONS

This application claims the benefit of and priority to Korean Patent Application No. 10-2024-0024575, filed on Feb. 20, 2024 and Korean Patent Application No. 10-2025-0009730, filed on Jan. 22, 2025, the entire disclosure(s) of which is hereby incorporated herein by reference in its entirety.

### BACKGROUND

### Field

The present disclosure relates to an insert and test system for testing a semiconductor product in a standing state.

### Description of Related Art

Semiconductor products that have gone through a production process undergo a certain test and are graded before being supplied to the market. This test is conducted by mounting the semiconductor product on a test system having a main board and then transmitting a signal for testing to the semiconductor product. The test uses various signals depending on the characteristics of the semiconductor product, and a thermal environment in which the test is conducted may also be changed as needed. The results of this test may be divided into A/B/C/D or the like, classified into good/defective/retest or the like, or determined in various other ways.

In order to automate testing for a large number of semiconductor products, an automated test system including a handler is used. In this case, a dedicated tray is used to transport and test a large number of semiconductor products at once. The tray has a shape similar to a straight plate and has grooves disposed in a plurality of rows and/or columns. One insert is inserted into each groove. The semiconductor product is moved and tested inside the test system together with the tray in a state of being loaded into any one insert.

At this time, the method of mounting the semiconductor product is done by electrically connecting a connection terminal of a test device to a terminal formed on the semiconductor product. Therefore, devices such as LPCAMM or dual in-line memory module (DIMM) whose terminals are located on the side surface of the semiconductor product are in close contact with the test device in a lying down state for mounting. In this case, the lying down state means a posture in which the side surface portion where the terminal is formed faces the floor.

However, devices such as the LPCAMM or dual in-line memory module (DIMM) usually have a form in which the length is much longer than the height of the side surface. Therefore, when these devices are laid down, the footprint occupied by the device is maximized. The method of arranging the device so that the device has the maximum footprint in a state of being mounted on the test device acts as a factor that limits the number of devices that can be tested at one time by the test device.

### SUMMARY

An object of the present disclosure is to provide an insert and test system that can minimize a footprint of a semiconductor product in a test state by testing the semiconductor product in a standing state.

Objects of the present disclosure are not limited to the object, and other objects not mentioned can be clearly understood by those skilled in the art from the description below.

In order to achieve the objects, an automated mounting test system for testing a semiconductor product in a standing state according to one embodiment of the present disclosure includes: a test tray including a plurality of inserts and having a tray groove into which each insert is inserted; a handler configured to load a semiconductor product to be tested into an empty insert and collect the tested semiconductor product from the insert; a tester including a plurality of socket modules, each facing one of the inserts, in a state where the test tray is seated; and a rack master configured to transport the test tray between the handler and the tester.

The insert includes an insert housing inserted into an inside of the tray groove, an insertion block supporting the semiconductor product in a standing posture while supporting the semiconductor product so that one surface of the semiconductor product is exposed to the tray groove, and a moving block connected to the insertion block and provided to be able to advance or retreat inside the insert housing.

The socket module includes a socket block accommodated in a free space of the tray groove in a state where the test tray is seated on the tester, and a connector which is positioned on one surface of the socket block, formed to transmit or receive signals for testing with the semiconductor product, and electrically connected to the semiconductor product by being in close contact with one surface of the semiconductor product by advancement of the moving block.

The insert may further include a support block that is provided to be able to advance or retreat inside the insert housing to push the moving block in a direction of the insertion block, and positioned on the back side of the semiconductor product in a state of contacting the moving block.

The insert may further include a push switch which protrudes upward from the insert housing, is lowered by an external force, and advances an end portion of the support block in the direction of the insertion block.

The support block may have a forward-movement-inducing inclined surface that is in contact with the push switch and is higher as getting closer to the insertion block.

The forward-movement-inducing inclined surface may include a first inclined surface that induces movement of the support block during a process in which the support block approaches the moving block, and a second inclined surface that induces movement of the support block during a process in which the support block pushes the moving block and has a steeper slope than that of the first inclined surface.

The support block may include a device alignment hole that is aligned with a through hole formed in the semiconductor product in a state where the semiconductor product is supported by the insertion block.

A pair of the insertion blocks disposed symmetrically to each other may be provided, and

each of the insertion blocks may have an insertion slot that extends in an up-down direction so that the semiconductor product approaches from above and is inserted into the insertion slot.

The insert may further include a holding member protruding into an inside of the insertion slot, and a device holding elastic member that elastically supports the holding member within the insertion block.

The socket block may include a block alignment pin extending parallel to a direction in which the insertion block approaches, so as to guide an advancement/retreat direction of the insertion block.

The connector may include a device alignment pin that extends parallel to the block alignment pin and is inserted into a through hole formed in the semiconductor product to align the semiconductor product.

The socket module may further include a seating plate on which the insert housing is seated, and in which a housing alignment pin inserted into the insert housing in a process of the insert housing being seated protrudes upward.

The seating plate may include a block accommodating groove which accommodates a lower end portion of the insertion block in a state where the insert housing is seated and is formed along an advancement/retreat direction of the insertion block.

In order to achieve the objects, an insert for testing a semiconductor product in a standing state according to one embodiment of the present disclosure includes: an insert housing inserted into an inside of a tray groove formed in a test tray; an insertion block supporting the semiconductor product in a standing posture while supporting the semiconductor product so that one surface of the semiconductor product is exposed to the tray groove; and a moving block connected to the insertion block and provided to be able to advance or retreat inside the insert housing.

Other specific details of the present disclosure are included in the detailed description and drawings.

According to the embodiments of the present disclosure, there are at least the following effects.

The number of semiconductor products tested in the same test space can be maximized.

By maximizing the number of semiconductor products tested at one time, the test time for a large number of semiconductor products can be efficiently shortened.

The effects according to the present disclosure are not limited to the contents exemplified above, and more diverse effects are included in the present specification.

### BRIEF DESCRIPTION OF THE DRAWING

FIG. 1 is a schematic overall perspective view of a test system according to one embodiment of the present disclosure.

FIG. 2 is a schematic view of a test tray and a tester module according to one embodiment of the present disclosure.

FIG. 3 is a view when the test tray according to one embodiment of the present disclosure is viewed from above.

FIG. 4 is a view when the tester module according to one embodiment of the present disclosure is viewed from above.

FIG. 5 is a schematic perspective view of a socket module according to one embodiment of the present disclosure.

FIG. 6 is a view illustrating an initial state of an insert according to one embodiment of the present disclosure.

FIG. 7 is a view illustrating a pressurized state of the insert according to one embodiment of the present disclosure.

FIG. 8 is a cross-sectional view of the initial state of the insert according to one embodiment of the present disclosure.

FIG. 9 is a view illustrating a situation inside the insert in the initial state of the insert according to one embodiment of the present disclosure.

FIG. 10 is a cross-sectional view of the pressurized state of the insert according to one embodiment of the present disclosure.

FIG. 11 is a view illustrating a situation inside the insert in the pressurized state of the insert according to one embodiment of the present disclosure.

FIG. 12 is a view for explaining a holding structure of a semiconductor product by an insertion block according to one embodiment of the present disclosure.

FIG. 13 is a view illustrating a semiconductor product being accommodated in the insert according to one embodiment of the present disclosure.

### DETAILED DESCRIPTION

The advantages and features of the present disclosure, as well as the methods for achieving them, will become clear with reference to embodiments described in detail below together with the attached drawings. However, the present disclosure is not limited to the embodiments disclosed below and may be implemented in various different forms, and these embodiments are provided only to ensure that the disclosure of the present disclosure is complete and to fully inform a person having ordinary skill in the art to which the present disclosure belongs of the scope of the invention, and the present disclosure is defined only by the scope of the claims.

In addition, the embodiments described in this specification will be described with reference to cross-sectional views and/or schematic views, which are ideal examples of the present disclosure. Accordingly, the form of the example drawings may be modified due to manufacturing technology and/or tolerances. In addition, each component in each drawing illustrated in the present disclosure may be illustrated to some extent enlarged or reduced for convenience of explanation. The same reference numerals refer to the same components throughout the specification.

Hereinafter, a “semiconductor product” referred to may mean a form in which a terminal for transmitting and receiving signals is disposed on the side surface, and may include both finished products and semi-finished products. For example, the semiconductor product may be DIMM or LPCAMM. In this case, the side surface may mean both surfaces having the widest surface in a thin plate-shaped semiconductor product. For example, the side surface may be the surface where semiconductor elements mounted on the semiconductor product are located.

In addition, the directions of up/down/front/back/left/right mentioned below are only explained to make it easy to understand the positions of other elements based on one reference point, and the present disclosure is not limited to such directions. For example, it is obvious that the invention may be installed and/or operated in a direction different from the description below during actual use, and the present disclosure is interpreted to include such embodiments.

Hereinafter, the present disclosure will be described with reference to drawings for explaining an insert and a test system for testing a semiconductor product in a standing state according to an embodiment of the present disclosure.

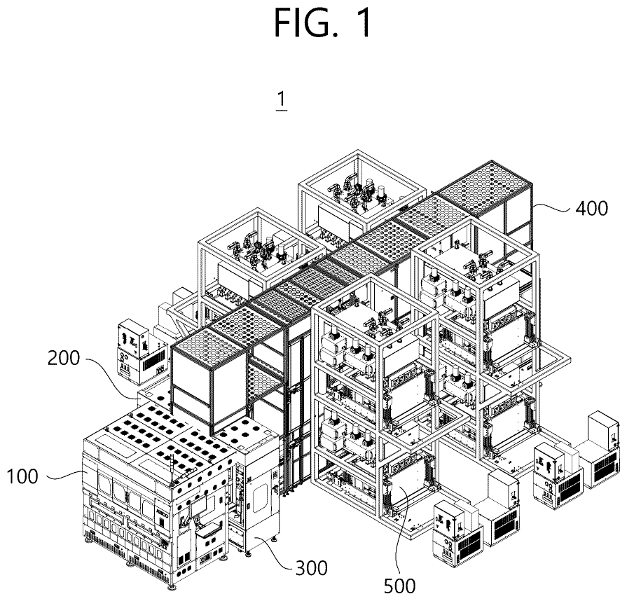

FIG. 1 is a schematic overall perspective view of a test system according to one embodiment of the present disclosure. The example illustrated in FIG. 1 is an exemplary appearance of a test system 1 according to one embodiment of the present disclosure, and the present disclosure is not limited to the appearance of FIG. 1. That is, although FIG. 1 illustrates one rack master 400 and eight testers 500 being disposed in response to one handler 100, the number of rack masters 400 and testers 500 for one handler 100 may vary depending on the environment of a user.

As illustrated in FIG. 1, the test system 1 according to one embodiment of the present disclosure may be configured to include the handler 100, the rack master 400, and the tester 500.

The handler 100 may be configured to load a semiconductor product to be tested into an empty insert and collect the tested semiconductor product from the insert. The semiconductor product to be tested may be supplied from the outside into the handler 100, and the tested semiconductor product may be delivered to the handler 100 after being tested in the tester 500. In order to properly transport the semiconductor product, a transport module for transporting the semiconductor product may be disposed inside the handler 100. For example, the handler 100 may be configured to include a stacker, a pick-and-place unit, a table, or the like to assist logistics using a user tray and the test tray.

Here, the user tray may be a tray on which a semiconductor product is loaded when the semiconductor product before a test is supplied to the handler 100 or the semiconductor product after a test is completed is transported to the outside. In addition, the test tray may be a tray on which the semiconductor product to be tested is transferred. A plurality of inserts may be positioned in the test tray so as to have an arrangement corresponding to the socket arrangement of the tester 500. The semiconductor product may be moved in a state of being loaded on the insert, tested, and then returned to the handler 100 in a state of being loaded on the test tray.

The pick-and-place unit of the handler 100 can be used to classify the semiconductor products by grade during the process of loading the semiconductor product loaded on the user tray to the insert of a test tray, moving the semiconductor product loaded on the insert to the user tray, or moving semiconductor products to the user tray. For example, the semiconductor products may be classified into good products, defective products, re-inspection products, or the like, or further classified as needed. In order to facilitate various logistics, the handler 100 may include a plurality of pick-and-place units.

A loader 200 is a unit that receives the user tray and semiconductor product from the outside and supplies them to the handler 100. The loader 200 may be implemented in various configurations as needed. The user trays and semiconductor products supplied to the loader 200 may be supplied by automated equipment or supplied by a worker.

The loader 200 may be placed in close contact with the handler 100 so that a semiconductor product transport path with respect to the handler 100 decreases. The pick-and-place unit and/or a transport module equivalent thereto may be positioned at a portion of the handler 100 in close contact with the loader 200 to introduce semiconductor products and/or user trays prepared inside the loader 200 into the interior of the handler 100. For example, the loader 200 may prepare semiconductor products on a user tray in units of 1 lot, and the handler 100 may insert at least a portion of 1 lot into each insert of the test tray so that the semiconductor products are accommodated in each insert. In this case, in the handler 100, an empty test tray where testing is completed and all semiconductor products are collected can be moved to the loader 200 in advance and placed on standby.

An unloader 300 may be a unit where products wait until the semiconductor product whose test has been completed is taken out. The unloader 300 maybe implemented in various configurations as needed. An empty user tray may be left in the unloader 300, and the empty user tray may be supplied by an automated device or supplied by a worker. Similar to the loader 200, the unloader 300 may be disposed in close contact with the handler 100 so that the semiconductor product transport path with the handler 100 decreases. A pick-and-place unit and/or a transport module equivalent thereto may be positioned at a portion of the handler 100 that is in close contact with the unloader 300 to transport the semiconductor product whose test has been completed to the user tray prepared inside the unloader 300.

In the unloader 300, the plurality of semiconductor products may be sorted by grade given according to the test results. Good semiconductor products are loaded by grade on the user trays disposed inside the unloader 300, and may then be taken out to the outside to undergo a subsequent process. In addition, defective semiconductor products may be loaded together with good products on a different user tray and may then be discarded. Similarly, semiconductor products of re-inspection grades are loaded on the same user tray, and then this user tray may be transferred back to the loader 200.

The rack master 400 may be a unit that transfers the test tray between the handler 100 and each tester 500. In the test system 1 according to one embodiment of the present disclosure, the rack master 400 may have a form that extends along the longitudinal direction with respect to the handler 100. That is, the rack master 400, the loader 200, and the unloader 300 may be positioned in close contact with one surface of the handler 100. In addition, the loader 200 and the unloader 300 may be positioned at positions symmetrical to each other with the rack master 400 therebetween. Therefore, according to one embodiment of the present disclosure, the loading operation of the loader 200, the transfer operation of the rack master 400, and/or the unloading operation of the unloader 300 may be performed serially on one surface of the handler 100. In addition, according to one embodiment of the present disclosure, the loader 200 and the unloader 300 are in close contact with both sides of the rack master 400, so that the transport distance of the semiconductor product inside the handler 100 can be shortened.

A front end portion of the rack master 400 in a longitudinal direction may be in close contact with the handler 100. At the front end of the rack master 400, exchange of the test tray between the handler 100 and the rack master 400 may be performed. A rear end portion of the rack master 400 is extended in the longitudinal direction, and the length of the rack master 400 may be determined according to the number of testers 500 to be installed. As the number of testers 500 increases, the length of the rack master 400 may also increase.

In order to reduce the length burden of the rack master 400, the tester 500 may be optionally disposed in a multi-layer structure. In this case, the rack master 400 may be configured to transport the test tray in the length direction as well as the height direction. Likewise, the testers 500 may be symmetrically disposed on both sides of the rack master 400 so that the length burden of the rack master 400 is reduced.

The rack master 400 is configured to receive the test tray for testing from the handler 100 and deliver the test tray to the tester 500 that can receive the test tray or to the tester 500 according to the set order. In addition, the rack master 400 is driven to collect the test tray for which the test has been completed from the tester 500 and deliver the test tray back to the handler 100.

Therefore, from the perspective of one test tray, the path circulating inside the system is as follows. First, the test tray is positioned close to the loader 200 in the handler 100, and then the semiconductor product waiting in the loader 200 is loaded into the empty insert. After that, the test tray is transported from inside the handler 100 to the rack master 400 side, and then transferred to the tester 500 by the rack master 400. When a series of tests are completed in the tester 500, the test tray is transported to the handler 100 by the rack master 400 again, and then transferred to the unloader 300. When all the loaded semiconductor products are collected by the unloader 300, the test tray is moved to a position adjacent to the loader 200 again, and the aforementioned process is repeated.

The tester 500 is configured to be able to exchange test trays with the rack master 400, and may be a unit for evaluating the performance of the semiconductor product. More specifically, the tester 500 may provide a predetermined temperature environment in a state of mounting the supplied test tray on a socket. For example, the tester 500 can test whether the semiconductor product operates normally in an environment ranging from −40 degrees Celsius to +130 degrees Celsius. A detailed description of the tester 500 will be described later.

In this case, since one embodiment of the present disclosure includes the plurality of testers 500, the plurality of testers 500 may be set to different test conditions as needed. For example, some of the plurality of testers 500 may be set to perform tests on the semiconductor products in a high-temperature environment, and others may be set to perform tests on the semiconductor products in a low-temperature environment. Alternatively, some and others of the plurality of testers 500 may be set to test different types of semiconductor products.

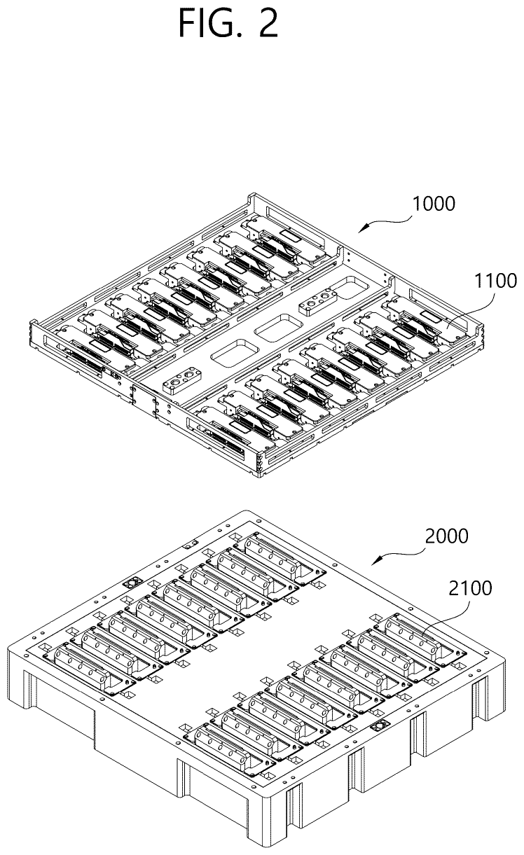

Hereinafter, based on the above description, a test tray and a tester module according to one embodiment of the present disclosure will be described with reference to FIG. 2. FIG. 2 is a schematic view of the test tray and the tester module according to one embodiment of the present disclosure.

A tester module 2000 may be a module that provides a space in which a test tray 1000 is seated in a tester 500 (refer to FIG. 1). The test tray 1000 may be transported to an upper position of the test module 2000 by a transport module located inside the tester 500, and then seated on the tester module 2000 while aligned with the tester module 2000. In this case, although not illustrated, the tester 500 may include a push module for bringing the test tray 1000 into close contact with the upper surface of the tester module 2000. The push module may press the frame of the test tray 1000 downward to bring the test tray 1000 into close contact with the tester module 2000.

Meanwhile, a plurality of socket modules 2100 may protrude from the upper surface of the tester module 2000 to face any one insert 1100 in a state where the test tray 1000 is seated. When the test tray 1000 is seated on the tester module 2000, each socket module 2100 may face the corresponding insert 1100 in a state of being accommodated in a groove formed in the test tray 1000.

The socket modules 2100 may be provided in the same number as the inserts 1100 inserted into the test tray 1000. As illustrated in FIG. 2, when the test tray 1000 is aligned above the test module 2000, each socket module 2100 is positioned in front of the corresponding insert 1100, and may be accommodated in the empty space in front of the insert 1100 during the process of lowering the test tray 1000.

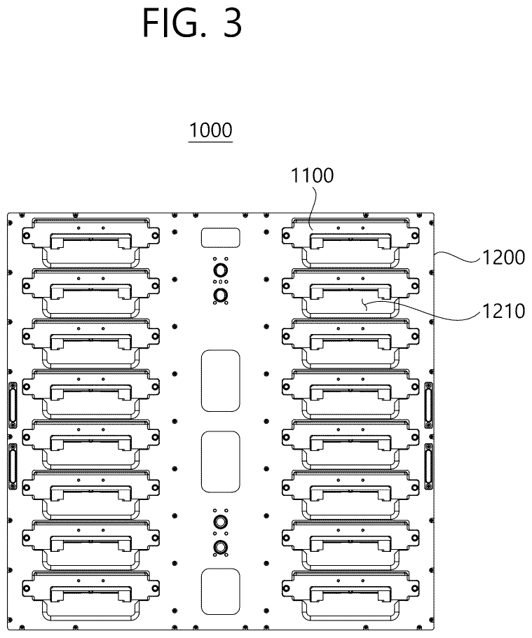

Hereinafter, the test tray 1000 according to one embodiment of the present disclosure will be described in detail with reference to FIG. 3. FIG. 3 is a view when the test tray according to one embodiment of the present disclosure is viewed from above.

As illustrated in FIG. 3, the test tray 1000 may be configured to include a tray body 1200 and the insert 1100. A plurality of inserts 1100 may be mounted on the tray body 1200. In this case, the plurality of inserts 1100 may be loosely mounted on the tray body 1200 and may be swayed in a state of being mounted.

The tray body 1200 may be a plate-shaped structure having a plurality of tray grooves 1210 into which the inserts 1100 may be inserted. In this case, the tray groove 1210 may be formed to correspond to the number of socket modules 2100 (refer to FIG. 2) of the tester module 2000 (refer to FIG. 2) and the arrangement of the socket modules 2100 on the tester module 2000. In addition, the size of the tray groove 1210 is formed to be larger than the bottom surface of the insert 1100, and thus, the tray groove 1210 has a free space in a state where the insert 1100 is inserted into the tray groove 1210.

The insert 1100 is provided in a shape that can be inserted into the tray groove 1210 and may be mounted on the tray body 1200 so as to be in close contact with the rear end side of the tray groove 1210. Accordingly, an empty space of the tray groove 1210 maybe located in front of the insert 1100, and the socket module 2100 described above may be accommodated in this space.

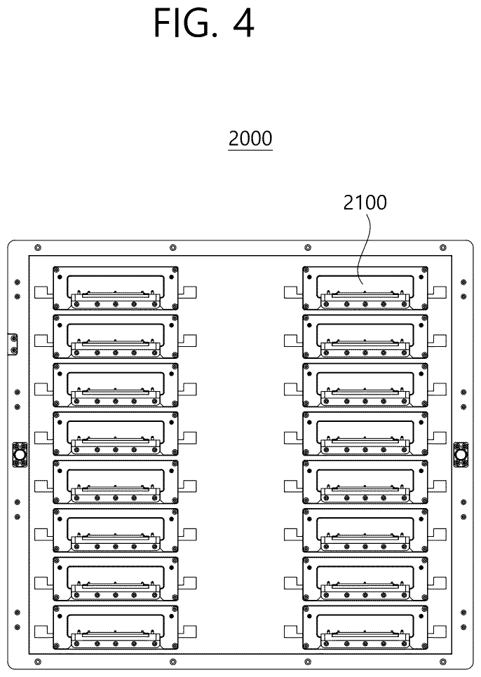

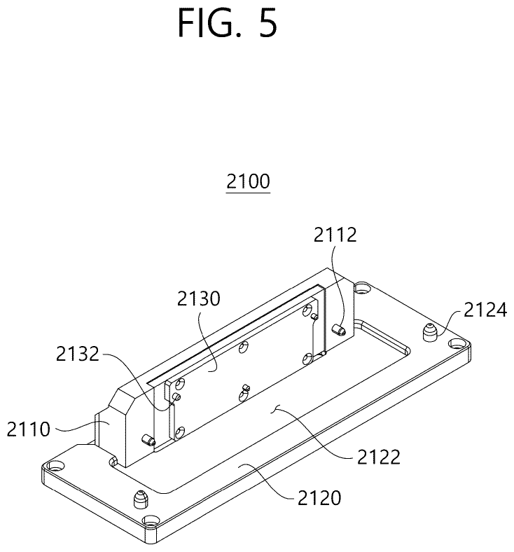

Hereinafter, with reference to FIGS. 4 and 5, the test module 2000 and the socket module 2100 according to one embodiment of the present disclosure will be described in detail.

First, FIG. 4 is a view when the tester module according to one embodiment of the present disclosure is viewed from above. As illustrated in FIG. 4, the socket module 2100 is formed on the upper surface of the tester module 2000 so as to correspond to the number and position of inserts in the tester tray.

The socket module 2100 is accommodated into the free space of the tray groove in a state where the test tray is seated on the tester, and is electrically connected to the semiconductor product when the push switch described below is pushed in a state where the push module presses the test tray. Each socket module 2100 may transmit or receive signals for testing with the electrically connected semiconductor product and transmit the response of the semiconductor product to the tester.

Continuing the description with reference to FIG. 5, FIG. 5 is a schematic perspective view of the socket module according to one embodiment of the present disclosure. As illustrated in FIG. 5, the socket module 2100 according to one embodiment of the present disclosure may include a socket block 2110, a seating plate 2120, and a connector 2130.

The socket block 2110 is a block-shaped member accommodated in the free space of the tray groove, and may be provided to support the front of the connector 2130. That is, the socket block 2110 may serve as a reinforcing member supporting the front of the connector 2130, thereby preventing the connector 2130 from being damaged by the force of the insert being pressed. In addition, a circuit for connecting the connector 2130 and the main board of the tester may be installed inside the socket block 2110.

At both ends of the socket block 2110, a block alignment pin 2112 extending toward the front may protrude. The block alignment pin 2112 may protrude in a direction parallel to the direction in which the insertion block described below approaches. The entire length of the socket block 2110, including the length of the block alignment pin 2112, may be formed to be shorter than the length of the free space of the tray groove described above. This is to prevent the block alignment pin 2112 from colliding with the insert during the process of the socket block 2110 being accommodated in the free space.

The connector 2130 that transmits and receives signals for testing in a state of being electrically connected to the semiconductor product may be disposed on the front surface of the socket block 2110. The connector 2130 is mainly formed in a plate shape, but a connection means for electrically connecting to the semiconductor product may be provided at a portion that comes into contact with the terminal of the semiconductor product. The connection means may be implemented in various ways known in the art, and may be provided as pogo pins, conductive rubber pads, or the like for example. The semiconductor product may be moved forward by the insert and may be in close contact with the connector 1230. By the pressurization of the insert, the semiconductor product is maintained in contact with the connector 1230, and accordingly, the connector 1230 and the semiconductor product can be maintained in an electrically connected state during the test period.

Similar to the block alignment pin 2112, a device alignment pin 2132 may protrude forward from the connector 2130. The device alignment pin 2132 is inserted into a through hole formed in the semiconductor product mounted on the insert, and can align the semiconductor product with respect to the connector 2130. In this case, the device alignment pin 2132 may extend parallel to the block alignment pin 2112, but a width or inner diameter thereof may be smaller than that of the block alignment pin 2112. In addition, the device alignment pin 2132 may protrude into the external space with a shorter length than the block alignment pin 2112 so that the block alignment pin 2112 and the insert interact first.

The seating plate 2120 may be a plate-shaped member that provides a surface on which the insert housing is seated. Housing alignment pins 2124 may protrude upward from both ends in the width direction of the seating plate 2120. The housing alignment pin 2124 is inserted into a corresponding insert during the process of seating the test tray, and may guide the downward direction of the insert. More specifically, the housing alignment pin 2124 is inserted into the insert housing described below, and may guide the seating position of the insert during the insertion process. To this end, the insert housing may have a groove formed to penetrate along the height direction on the bottom surface to allow the housing alignment pin 2124 to be inserted. Since the insert is loosely mounted to the tray body, the insert swings relative to the tray body, and is seated at an accurate seating position by the housing alignment pin 2124.

On the upper surface of the seating plate 2120, a block accommodating groove 2122 may be formed to accommodate a lower end portion of an insertion block be described later in a state where the insert is seated. The block accommodating groove 2122 may be formed by recessing the upper surface of the seating plate 2120 along a path along which a pair of insertion blocks advance or retreat. Each of the pair of insertion blocks may advance or retreat in a state where one side surface thereof leans against a side wall forming the block accommodating groove 2122.

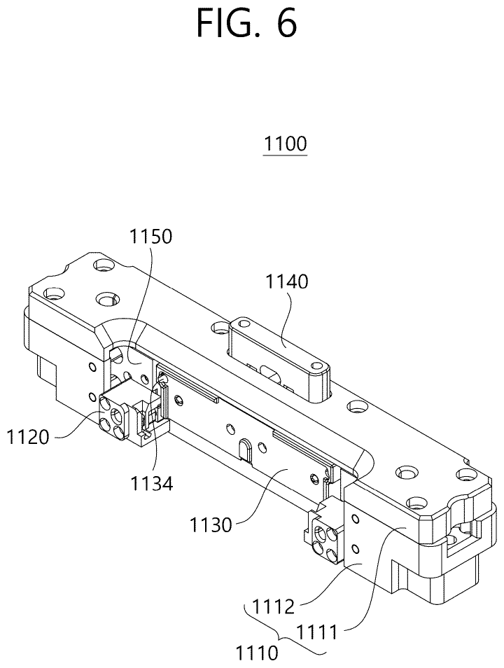

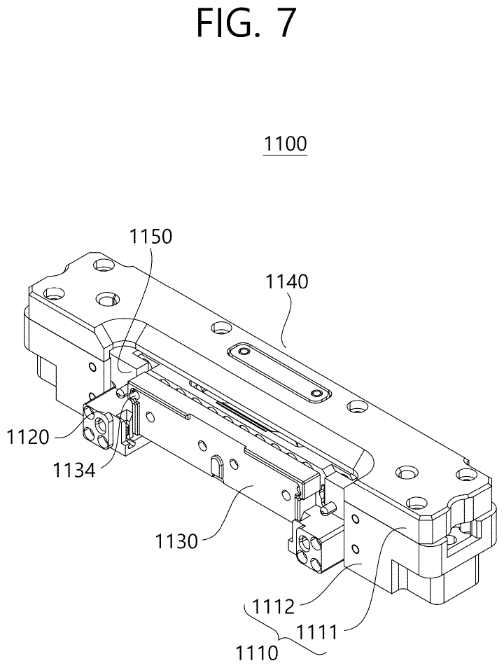

Hereinafter, the insert 1100 according to one embodiment of the present disclosure will be described with reference to FIGS. 6 to 11. First, FIG. 6 is a view illustrating an initial state of the insert according to one embodiment of the present disclosure. In relation to this, FIG. 7 is a view illustrating a pressurized state of the insert according to one embodiment of the present disclosure.

Referring to FIGS. 6 and 7, the insert 1100 according to one embodiment of the present disclosure may include an insert housing 1110, an insertion block 1120, a support block 1130, a moving block 1150, and a push switch 1140.

The insert housing 1110 is a member that forms the basic skeleton of the insert 1100 and may be provided in a shape that can be inserted into a tray groove. As described above, the insert housing 1110 may be mounted in close contact with the rear end of the tray groove. The insert housing 1110 may be provided in a shape of a rectangular parallelepiped having an approximately long width.

Meanwhile, the insert housing 1110 may be divided into an upper housing 1111 and a lower housing 1112. The lower housing 1112 may have an internal space and may be provided to accommodate most of the other components of the insert 1100 in the internal space. The upper housing 1111 may be coupled to the upper surface of the lower housing 1111 to function as a lid for the lower housing 1112.

A groove into which the aforementioned block alignment pin may be inserted may be formed to penetrate the front surface of the lower housing 1112 along the longitudinal direction. In addition, a groove into which the aforementioned housing alignment pin may be inserted may be formed to penetrate the bottom surface of the lower housing 1112 along the height direction. Meanwhile, an opening through which the push switch 1140 protrudes or retracts may be formed in the center of the upper surface of the upper housing 1111.

The insertion block 1120 is a block that supports the semiconductor product so that the side surface of the semiconductor product is exposed to the tray groove. In this case, the insertion block 1120 can support the semiconductor product in a standing posture. At this time, the standing posture may be a posture in which the side surface of the semiconductor product where the terminal is formed faces forward. For example, the standing posture may be a posture in which the semiconductor product is approximately vertically upright on the ground.

In this case, a pair of the insertion block 1120 may be provided to be symmetrically disposed at a certain interval from each other on the front end portion of the lower housing 1111. The pair of insertion blocks 1120 may be configured to support the semiconductor product inserted therebetween together. The semiconductor product may be lowered from the upper side of the insert 1100 and inserted between the pair of insertion blocks 1120. The pair of insertion blocks 1120 may support the left lower end portion and the right lower end portion of the inserted semiconductor product, respectively.

The moving block 1150 is formed so as to be able to move in a direction approaching or moving away from the insertion block 1120 inside the insert housing 1110, so as to move the insertion block 1120 relative to the insert housing 1110. To this end, the moving block 1150 may be integrally connected to the insertion block 1120 by a conventionally known fixing means. For example, the moving block 1150 may be connected to the insertion block 1120 through a fastener connection.

The moving block 1150 may be provided as a pair corresponding to each insertion block 1120, and can advance or retreat in the space between the upper housing 1111 and the lower housing 1112. In the initial state, the moving block 1150 is accommodated to the maximum extent inside the lower housing 1112 as illustrated in FIG. 6, and when changed to a pressurized state, the moving block 1150 protrudes forward of the lower housing 1112 as illustrated in FIG. 7 and moves the insertion block 1120 forward.

The support block 1130 is provided to move forward by an external force that pressurizes the push switch 1140, and may push the moving block 1150 forward during the process of the advancing. That is, the moving block 1150 may be pressed forward by the advancing support block 1130 and may advance together with the support block 1130. To this end, the support block 1130 may be formed to be able to advance or retreat inside the lower housing 1112.

The support block 1130 may advance alone until the push switch 1140 is pressed to a certain depth, and when the support block is pressed beyond a certain depth, the support block may come into contact with the moving block 1150 and advance together. As illustrated in FIG. 7, when the support block 1130 and the moving block 1150 are in contact with each other, the front surface of the support block 1130 may be positioned slightly rearward with respect to the center of the insertion block 1120. In this state, the front surface of the support block 1130 is positioned adjacent to the rear side of the semiconductor product inserted into the insertion block 1120. More specifically, in this state, the front surface of the support block 1130 may be positioned slightly rearward than the insertion slot described later. In this case, the support block 1130 does not directly contact the semiconductor product, but may play a role in preventing the rear surface of the semiconductor product from being excessively bent or shaken and damaged during the movement or testing process. Alternatively, the support block 1130 may be in direct contact with the semiconductor product and may support the semiconductor product during the test process.

Meanwhile, a device alignment hole 1134 may be formed on the front surface of the support block 1130 to be aligned with a through hole of the semiconductor product inserted into the insertion block 1120. The device alignment hole 1134 may be formed by being recessed backward along the length direction on the front surface of the support block 1130. During the process of advancing the insertion block 1120, the device alignment pin of the socket module may pass through the through hole of the semiconductor product and then be finally accommodated in the device alignment hole 1134.

The push switch 1140 may be disposed to be retractable from the insert housing 1110 through the opening of the upper housing 1111. In the initial state as illustrated in FIG. 6, the upper end portion of the push switch 1140 may protrude outward from the insert housing 1110 through the opening, and the lower end portion may be accommodated inside the lower housing 1112. When the pressurized state as illustrated in FIG. 7 is reached, the push switch 1140 is accommodated to the maximum extent in the lower housing 1112, and the support block 1130, the moving block 1150, and the insertion block 1120 advance based on the external force that lowers the push switch 1140. In this case, the pressurization of the push switch 1140 may be implemented by the push module installed in the tester.

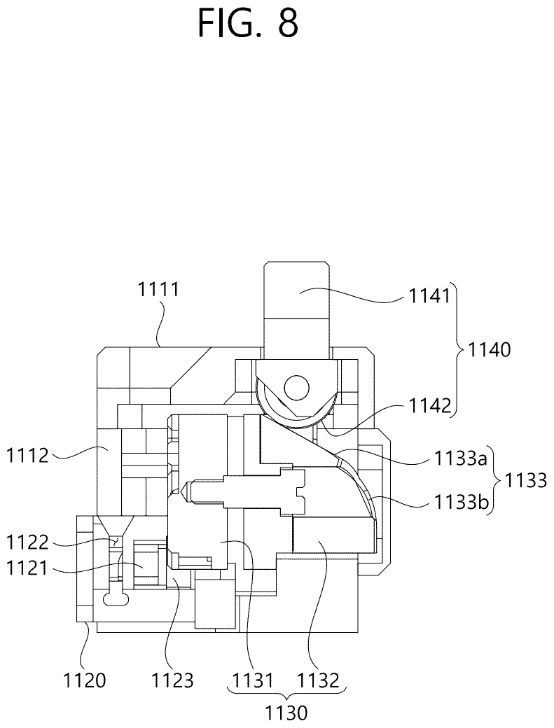

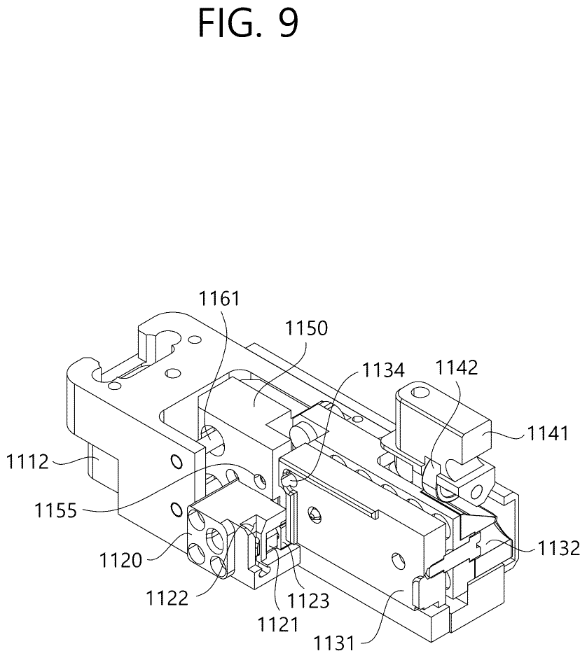

Hereinafter, with reference to FIGS. 8 and 9, the initial state of the insert according to one embodiment of the present disclosure will be described in detail. FIG. 8 is a cross-sectional view of the initial state of the insert according to one embodiment of the present disclosure. In this regard, FIG. 9 is a view illustrating the situation inside the insert in the initial state of the insert according to one embodiment of the present disclosure.

In this case, before explaining the initial state, each component of the insert will be additionally explained.

First, the push switch 1140 may include a switch body 1141 and a pressure wheel 1142. The switch body 1141 may be a member having a substantially rectangular shape, and may be a portion that protrudes or retracts from the opening of the upper housing 1111.

The pressure wheel 1142 may be a disc-shaped member that is rotatably mounted on at least one lower end portion of the switch body 1141. The pressure wheel 1142 comes into contact with the rear end portion of the support block 1130 and may transmit an external force to the rear end portion of the support block 1130. When the switch body 1141 is lowered by an external force, the pressure wheel 1142 may roll on the surface of the support block 1130 and gently push the rear end portion of the support block 1130 forward. In this case, in order to secure a predetermined friction performance between the support block 1130 and the pressure wheel 1142, the pressure wheel 1142 may be provided with a material having high friction at a portion that comes into contact with the support block 1130.

Meanwhile, the support block 1130 may be divided into a front block 1131 and a rear block 1132. Referring to FIGS. 8 and 9, the front block 1131 may be an approximately flat plate shaped member, and the rear block 1132 may be in the shape of an approximately triangular pillar having some curved sections. The front block 1131 and the rear block 1132 may be fastened to each other with fasteners so that they may move together.

Alternatively, the front block 1131 may be assembled to be able to advance or retreat relative to the rear block 1132 in a state of being assembled to the rear block 1132. In this case, a known elastic member may be disposed between the front block 1131 and the rear block 1132. The known elastic member may be, for example, a coil spring. Due to this, the size of the force that presses the semiconductor product in a state where the front block 1131 is in close contact with the connector may be adjusted according to the situation.

For example, in a general situation, the elastic member may provide an elastic force in the direction of pressing the front block 1131 forward to bring the semiconductor product into close contact with the socket module. The semiconductor product may be uniformly pressed by the front block 1131 and may be in uniform contact with the connector. Due to this, the semiconductor product may be stably maintained in contact with the connector during the test process. Meanwhile, when the semiconductor product is incorrectly mounted or the pressing force due to the insert is excessively set, the elastic force between the front block 1131 and the rear block 1132 may mainly act in the direction of pushing the rear block 1132 backward. Due to this, the magnitude of the force acting on the semiconductor product is weakened compared to the set force, and accordingly, excessive pressure is prevented from being applied to the semiconductor product and the socket module.

In the rear block 1132, a forward-movement-inducing inclined surface 1133 having a slope that increases in height as the forward-movement-inducing inclined surface approaches the insertion block 1120 may be formed at the contact portion of the push switch 1140. The forward-movement-inducing inclined surface 1133 induces a component of the external force applied to the support block 1130 from the pressure wheel 1142 to be directed forward at the contact surface during the process of lowering the pressure wheel 1142.

This forward-movement-inducing inclined surface 1133 includes a first inclined surface 1133a and a second inclined surface 1133b. First, the first inclined surface 1133a may induce movement of the support block 1130 during the process of the support block 1130 approaching the moving block 1150. In addition, the second inclined surface 1133b may induces movement of the support block 1130 in the process of further advancing the support block 1130 after the support block 1130 and the moving block 1150 come into contact with each other.

The first inclined surface 1133a has a relatively gentle slope and may not have a large change in slope. In contrast, the second inclined surface 1133b may have a steeper slope than the first inclined surface 1133a, and the slope of the second inclined surface may become larger as the second inclined surface moves away from the first inclined surface 1133a. To this end, the second inclined surface 1133b may be provided in a curved shape in which the slope becomes larger as the second inclined surface moves away from the first inclined surface 1133a. In this case, a steeper slope may mean that the slope is closer to vertical.

This inclination can induce the support block 1130 to move at a lower speed from the time the support block comes into contact with the moving block 1150 and presses the moving block 1150, even though the support block approaches the moving block 1150 relatively quickly until the support block approaches the moving block. This is because the insertion block 1120 moves together from the section where the moving block 1150 moves, so that the insertion block 1120 moves at a lower speed by gradually slowing down the moving speed of the support block 1130. As a result, according to one embodiment of the present disclosure, the semiconductor product is relatively slowly brought into close contact with the socket module, and damage to the semiconductor product and the socket module can be minimized during the pressing process.

In the above-described example, the forward-movement-inducing inclined surface 1133 is divided into two inclined surfaces having different inclinations, but the present disclosure is not necessarily limited to such an embodiment. For example, the forward-movement-inducing inclined surface 1133 may be formed by only one of the first inclined surface 1133a and the second inclined surface 1133b. Alternatively, the forward-movement-inducing inclined surface 1133 may be formed by a single inclined surface having an inclination different from those of the first inclined surface 1133a and the second inclined surface 1133b. Alternatively, the forward-movement-inducing inclined surface 1133 may be subdivided into a greater number of inclined surfaces.

Meanwhile, the insert may further include a shaft 1161 for guiding the advancing/retreating movement of the moving block 1150. The shaft 1161 may extend in the longitudinal direction inside a lower housing 1121, and both end portions may be fixed to the inner wall of the lower housing 1121.

In addition, although not illustrated, the insert may include an initial state restoration elastic member that provides a restoring force to maintain the initial state in the absence of an external force. The initial state restoration elastic member may be disposed between the front surface of the moving block 1150 and the inner wall of the lower housing 1112, and may elastically support the moving block 1150 toward the rear. For example, the initial state restoration elastic member may be provided as a helical spring or may be provided in a form similar to the helical spring.

Hereinafter, the initial state of the insert according to one embodiment of the present disclosure will be described with reference to FIGS. 8 and 9. In the initial state, the pressure wheel 1142 of the push switch 1140 may be in contact with the front end portion of the first inclined surface 1133a. Referring to FIG. 9, in this state, the moving block 1150 and the support block 1130 do not contact each other and may be separated from each other.

In addition, in the initial state, the insertion block 1120 may be in maximum contact with the insert housing 1110. In this case, the upper housing 1111 and the lower housing 1112 may not protrude upwardly from the insertion block 1120. More specifically, the upper housing 1111 and the lower housing 1112 may not protrude upwardly from the portion of the insertion block 1120 where an insertion slot 1122 is located. This is to prevent the insert housing 1110 from interfering when the semiconductor product is inserted into the insertion block 1120 in the initial state. That is, the insertion slot 1122 is not covered by the insert housing 1110 even in the initial state.

In addition, the support block 1130 may be accommodated to the maximum extent inside the lower housing 1112 in the initial state. Accordingly, the support block 1130 may be positioned furthest from the insertion block 1120 in the initial state. In this case, the front block 1131 may be positioned inside the lower housing 1112, and the rear block 1132 may be in contact with the inner wall of the lower housing 1112. The support of the rear block 1132 by the inner wall of the lower housing 1112 prevents the rear block 1132 from being pushed back any further by the elastic force of the initial state restoration elastic member.

Afterwards, when the push switch 1140 is pressed, the first inclined surface 1133a moves forward while the pressure wheel 1142 is lowered. When the pressure wheel 1142 reaches a boundary between the first inclined surface 1133a and the second inclined surface 1133b or the vicinity of the boundary, the support block 1130 and the moving block 1150 come into contact with each other, and the front surface of the front block 1131 is positioned behind the insertion slot 1122.

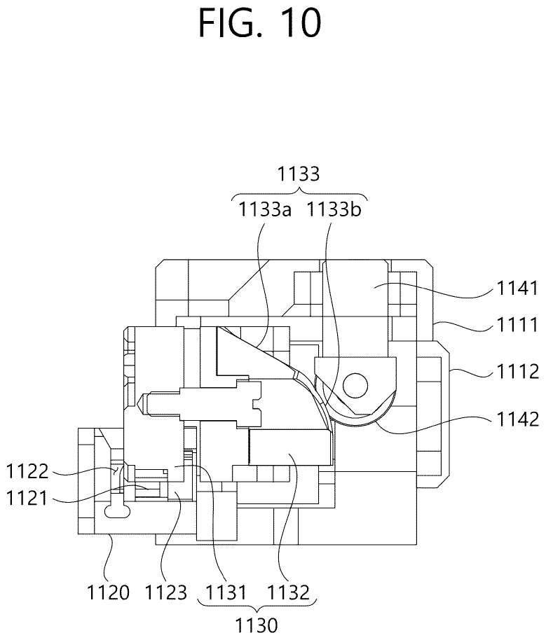

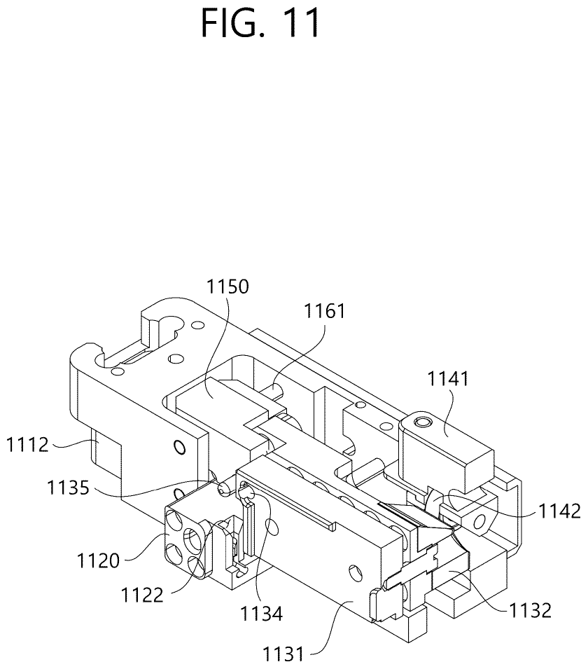

Hereinafter, the pressurized state of the insert according to one embodiment of the present disclosure will be described with reference to FIGS. 10 and 11.

FIG. 10 is a cross-sectional view of the pressurized state of the insert according to one embodiment of the present disclosure. In this regard, FIG. 11 is a view illustrating the situation inside the insert in the pressurized state of the insert according to one embodiment of the present disclosure.

As illustrated in FIGS. 10 and 11, in the pressurized state according to one embodiment of the present disclosure, the switch body 1141 is accommodated to the maximum extent inside the insert housing 1110, and as a result, the support block 1130 advances to the maximum extent. In this case, in the process of switching to the pressurized state, the forward speed of the support block 1130 is gradually reduced due to the inclination of the second inclined surface 1133b.

When the moving block 1150 is switched to a pressurized state, the moving block overcomes the elastic force of the initial state restoration elastic member by the pressurization by the support block 1130 and moves forward along the shaft 1161. When the moving block 1150 is in close contact with the inner wall of the lower housing 1112 and cannot advance any further, the switching to a pressurized state is completed.

In order for the support block 1130 to advance straightly toward the moving block 1150 and push the moving block 1150 in a straight direction, a protruding pin 1135 may be formed on the front of the rear block 1132 so as to protrude toward the rear of the moving block 1150. The protruding pin 1135 may protrude at a vertical angle from the front of the rear block 1132 so as to be parallel to the advancement/retreat direction of the rear block 1132. In response to this, a pin accommodating groove 1155 (refer to FIG. 9) which accommodates the protruding pin 1135 to be advanced or retreated may be formed to penetrate the moving block 1150 in the longitudinal direction at a portion of the moving block 1150 facing the protruding pin 1135. An inner diameter of the pin accommodating groove 1155 may be set to be slightly larger than that of the protruding pin 1135.

When the push switch 1140 is pressurized, the support block 1130 advances and the protruding pin 1135 first enters the inside of the pin accommodating groove 1155. For example, the protruding pin 1135 may be inserted into the inside of the pin accommodating groove 1155 and advance while the push switch 1140 pushes the first inclined surface 1133a of the support block 1130. When the rear end portion of the protruding pin 1135 is completely accommodated in the pin accommodating groove 1155, the front surface of the rear block 1132 can come into contact with the rear surface of the moving block 1150. That is, when the pressurized wheel 1142 comes into contact with the second inclined surface 1133b, the protruding pin 1135 may be completely inserted into the pin accommodating groove 1155.

Meanwhile, the protruding pin 1135 is provided to be longer than the pin accommodating groove 1155 so that the protruding pin 1135 can protrude outward from the moving block 1150 in the pressurized state. This may be to facilitate the restoration of the insert to the initial state by pressing the protruding pin 1135 from the outside when the push switch 1140 fails to return to an original position of the push switch due to deterioration of the initial state restoration elastic member or other reasons.

In addition, in the pressurized state, the front block 1131 is positioned behind the insertion slot 1122, so that the semiconductor product can be prevented from shaking excessively while the process of the insertion block 1120 advances. In this case, in order to prevent damage to the components installed at the center of the semiconductor product during the process in which the front block 1131 advances, it is necessary to prevent the components from coming into contact with the front block 1131. To this end, the front surface of the front block 1131 may be provided with a stepped shape in which the center portion is recessed rearward relative to the edge portion. The components coupled to the semiconductor product can face the recessed portion in the front surface of the front block 1131 in a state where the semiconductor product is accommodated in the insertion block 1120. Therefore, when the front block 1131 is advanced as much as possible, the edge portion of the semiconductor product is supported by the edge portion protruding from the front block 1131, and the components installed in the semiconductor product may be accommodated in the recessed portion of the front block 1131. In this case, the depth of the recessed portion of the front block 1131 may be set so that the front block does not directly contact the components of the semiconductor product even when the front block 1131 is advanced as much as possible.

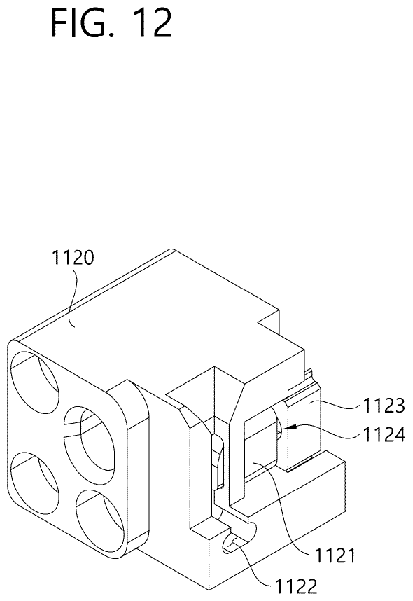

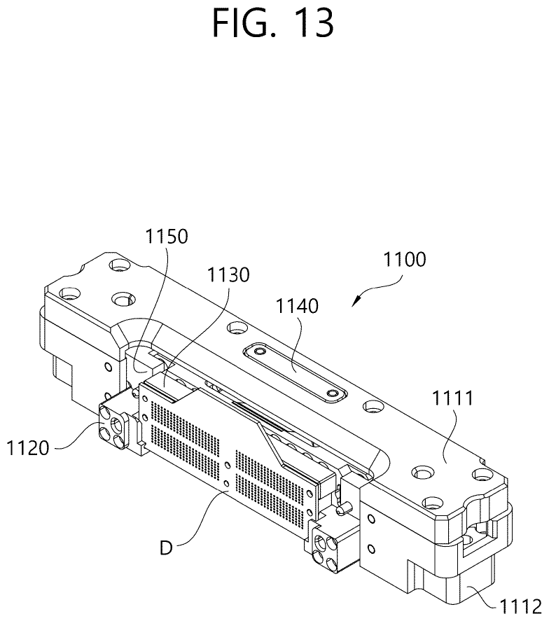

Hereinafter, with reference to FIGS. 12 and 13, a method of accommodating the semiconductor product by the insert according to one embodiment of the present disclosure will be described.

FIG. 12 is a view for explaining a holding structure of the semiconductor product by the insertion block according to one embodiment of the present disclosure. In this regard, FIG. 13 is a view illustrating a semiconductor product being accommodated in an insert according to one embodiment of the present disclosure.

As illustrated in FIG. 12, an insertion slot 1122 extending in an up-down direction (height direction) may be formed in the insertion block 1120 so that the semiconductor product may be approached from above and inserted into the insertion slot. More specifically, the insertion slot 1122 may be formed on a surface facing each other in the pair of insertion blocks 1120 and may extend mainly along the height direction. In this case, the lower end portion of the insertion slot 1122 may be bent at a vertical angle relative to the height direction and may be further extended in a horizontal direction (width direction). The semiconductor product may be accommodated in a portion where the left end or the right end extends in the height direction from the insertion slot 1122 and the lower end extends in the horizontal direction.

Meanwhile, the insert may include a holding member 1121 protruding into the interior of the insertion slot 1122 for stable holding of the semiconductor product. The holding member 1121 may be placed inside a placement groove 1124 that penetrates in the longitudinal direction to meet the insertion slot 1122 in the insertion block 1120. In this case, the holding member 1121 is mainly disposed inside the placement groove 1124, but the front end portion may protrude into the interior of the insertion slot 1122.

A support end 1123 may be disposed on the rear end portion of the placement groove 1124. The support end 1123 may be disposed to support the rear end portion of the device holding elastic member. The device holding elastic member may be provided to elastically support the holding member 1121 toward the front inside the insertion block 1120. For example, the device holding elastic member may be a helical spring whose front end is connected to the holding member 1121 and whose rear end is connected to the support end 1123.

When the semiconductor product is inserted into the insertion slot 1122, the holding member 1121 overcomes the elastic force and may be retracted toward the placement groove 1124. In this case, since the holding member 1121 tries to move forward due to the elastic force, the semiconductor product can be held inside the insertion slot 1122 without shaking by the holding member 1121. In this case, in the process of inserting the semiconductor product into the insertion slot 1122, the holding member 1121 may be provided with a curved upper surface so that the holding member 1121 can be smoothly pushed backward after coming into contact with the semiconductor product.

Referring to FIG. 13, continuing the explanation, as illustrated in FIG. 13, the semiconductor product D may be mounted on the insert 1100 in a state of being hugged by the pair of insertion blocks 1120. The semiconductor product D may be inserted into the insert 1100 by the pick-and-place device included in the handler or the like, or may be collected from the insert 1100. Since the pick-and-place devices have been known in various forms in the related art, their descriptions are omitted. For example, the semiconductor product D can be moved upwards on the insert 1100 so as to be positioned between the pair of insertion slots 1120, and then lowered as is to be mounted on the insert 1100.

In this case, the side surface on which the terminal is formed on the semiconductor product D may be exposed to the space in front of the insert 1100. Meanwhile, when the insert 1100 is placed on the test device, the socket module may be positioned in front of the semiconductor product D. When the push switch 1140 is pressurized by the push module of the tester, the semiconductor product D may advance along the moving block 1150 and the insertion block 1120. When the insert 1100 is completely switched to the pressurized state, the side surface of the semiconductor product D may be in close contact with the connector of the socket module. While the test of the semiconductor product D is in progress, the insert 1100 remains in the pressurized state, and when the test is finished, the insert may be switched back to the initial state. After that, the test tray is collected by the rack master and moved to the handler, and the semiconductor products D inserted into the insert 1100 may be finally collected and sorted by grade.

A person having ordinary skill in the art to which the present disclosure belongs will understand that the present disclosure can be implemented in other specific forms without changing the technical idea or essential features thereof. Therefore, the embodiments described above should be understood as being exemplary in all respects and not limiting. The scope of the present disclosure is indicated by the claims described below rather than the detailed description above, and all changes or modifications derived from the meaning and scope of the claims and their equivalent concepts should be interpreted as being included in the scope of the present disclosure.

1. An automated mounting test system for testing a semiconductor product in a standing state, the automated mounting test system comprising:
a test tray including a plurality of inserts and having a tray groove into which each insert is inserted;
a handler configured to load a semiconductor product to be tested into an empty insert and collect the tested semiconductor product from the insert;
a tester including a plurality of socket modules, each facing one of the inserts, in a state where the test tray is seated; and
a rack master configured to transport the test tray between the handler and the tester;
wherein the insert includes
an insert housing inserted into an inside of the tray groove,
an insertion block supporting the semiconductor product in a standing posture while supporting the semiconductor product so that one surface of the semiconductor product is exposed to the tray groove, and
a moving block connected to the insertion block and provided to be able to advance or retreat inside the insert housing, and
the socket module includes
a socket block accommodated in a free space of the tray groove in a state where the test tray is seated on the tester, and
a connector which is positioned on one surface of the socket block, formed to transmit or receive signals for testing with the semiconductor product, and electrically connected to the semiconductor product by being in close contact with one surface of the semiconductor product by advancement of the moving block.

2. The automated mounting test system of claim 1, wherein the insert further includes a support block that is provided to be able to advance or retreat inside the insert housing to push the moving block in a direction of the insertion block, and positioned on the back side of the semiconductor product in a state of contacting the moving block.

3. The automated mounting test system of claim 2, wherein the insert further includes a push switch which protrudes upward from the insert housing, is lowered by an external force, and advances an end portion of the support block in the direction of the insertion block.

4. The automated mounting test system of claim 3, wherein the support block has a forward-movement-inducing inclined surface that is in contact with the push switch and is higher as getting closer to the insertion block.

5. The automated mounting test system of claim 4, wherein the forward-movement-inducing inclined surface includes
a first inclined surface that induces movement of the support block during a process in which the support block approaches the moving block, and
a second inclined surface that induces movement of the support block during a process in which the support block pushes the moving block and has a steeper slope than that of the first inclined surface.

6. The automated mounting test system of claim 2, wherein the support block includes a device alignment hole that is aligned with a through hole formed in the semiconductor product in a state where the semiconductor product is supported by the insertion block.

7. The automated mounting test system of claim 1, wherein a pair of the insertion blocks disposed symmetrically to each other is provided, and
each of the insertion blocks has an insertion slot that extends in an up-down direction so that the semiconductor product approaches from above and is inserted into the insertion slot.

8. The automated mounting test system of claim 7, wherein the insert further includes
a holding member protruding into an inside of the insertion slot, and
a device holding elastic member that elastically supports the holding member within the insertion block.

9. The automated mounting test system of claim 1, wherein the socket block includes a block alignment pin extending parallel to a direction in which the insertion block approaches, so as to guide an advancement direction of the insertion block.

10. The automated mounting test system of claim 9, wherein the connector includes a device alignment pin that extends parallel to the block alignment pin and is inserted into a through hole formed in the semiconductor product to align the semiconductor product.

11. The automated mounting test system of claim 1, wherein the socket module further includes a seating plate on which the insert housing is seated, and in which a housing alignment pin inserted into the insert housing in a process of the insert housing being seated protrudes upward.

12. The automated mounting test system of claim 11, wherein the seating plate includes a block accommodating groove which accommodates a lower end portion of the insertion block in a state where the insert housing is seated and is formed along an advancement direction of the insertion block.

13. An insert for testing a semiconductor product in a standing state, the insert comprising:
an insert housing inserted into an inside of a tray groove formed in a test tray;
an insertion block supporting the semiconductor product in a standing posture while supporting the semiconductor product so that one surface of the semiconductor product is exposed to the tray groove; and
a moving block connected to the insertion block and provided to be able to advance or retreat inside the insert housing.
